(19) United States
(12) Patent Application Publication
(10) Pub. No.: US 2013/0249715 A1
(43) Pub. Date: Sep. 26, 2013

(54) KEYBOARD DEVICE FOR DIFFERENT OPERATING SYSTEMS

(71) Applicants: Yu-Yen Shih, Taipei (TW); Yi-Guang Chen, Taipei (TW)

(72) Inventors: Yu-Yen Shih, Taipei (TW); Yi-Guang Chen, Taipei (TW)

(73) Assignee: PRIMAX ELECTRONICS LTD., Taipei (TW)

(21) Appl. No.: 13/479,028

(22) Filed: May 23, 2012

(30) Foreign Application Priority Data
Mar. 23, 2012 (TW) 101110108

(51) Int. Cl. H03M 11/00

(52) U.S. Cl. 341/22

(57) ABSTRACT

The present invention discloses a keyboard device for different operating systems in communication with an electronic apparatus. The keyboard device includes at least a key and a control unit. When the control unit recognizes that a first operating system is installed in the electronic apparatus, the control unit outputs a corresponding first key signal in response to the first key code generated by the key, such that the electronic apparatus executes a first key command. When the control unit recognizes that a second operating system is installed in the electronic apparatus, the control unit switches the first key code into a second key code and then outputs a corresponding second key signal, such that the electronic apparatus still executes the first key command.

### FIELD OF THE INVENTION

The present invention generally relates to a keyboard device, and more particularly to a keyboard device capable of being applied to different operating systems.

### BACKGROUND OF THE INVENTION

Here in the technology and information age, the computer and peripherals thereof has become a part of the daily life of everybody whether at work or entertainment, and the input devices, such as the mouse device, the keyboard device, the trackball device and so on, used as the communication between the computer and the user has attracted increasing attention.

An object herein is concentrated in a keyboard device among the input devices, and a structure of a conventional keyboard device is illustrated hereinafter. FIG. 1 illustrates an external structural schematic view of a conventional keyboard device. Referring to FIG. 1, the conventional keyboard device 1 comprises a plurality of keys 10, wherein the plurality of keys are exposed by a surface of the conventional keyboard device 1, and the plurality of keys 10 can be categorized into common keys 101, number keys 102, function keys 103 and expansion keys 104 and so on.

Each one of the keys is capable of being pressed down by a user with his finger, so as to generate a corresponding key signal to an electronic apparatus, and thus the electronic apparatus are enabled to execute a function of the key being pressed down. Herein, it is able to key in an English letter, a special symbol or a standard command by pressing down any one of the common keys 101. For example, a surface of a key cap of the key “C” of the common keys 101 is presented with an English letter character “C”, and it is able to key in an English letter C by pressing down it, while it is able to execute a certain standard command by pressing down the key “Ctrl”. In addition, it is able to key in a number by pressing down any one of the number keys 102, it is able to execute a function, such as any one of F1 to F12, by pressing down any one of the function keys 103, while it is able to execute a command of Delete, a command of shifting to Home, a command of shifting to End, a command of Pageup, a command of Pagedown, a command of moving upward, a command of moving downward, a command of moving leftward and a command of moving rightward and so on by pressing down any one of the expansion keys 104.

The conventional keyboard device 1 is capable of being in communication with an electronic apparatus (not shown), so as to operate the electronic apparatus by using the conventional keyboard device 1. In general, the electronic apparatus is certainly installed with an operating system (OS), so as to provide a user interface (UI) for enabling the user to operate the electronic apparatus. The electronic apparatus in communication with the conventional keyboard device 1 can be installed with a Windows operating system (OS), wherein the electronic apparatus is a desktop host. As illustrated in FIG. 1, the keyboard device 1 further comprises a control unit 11, wherein the control unit 11 is disposed within the conventional keyboard device 1, in communication with each one of the foregoing keys, and capable of recognizing which one of the forgoing keys is pressed down by the user. In detail, in the conventional keyboard device 1, when one of the forgoing keys is pressed down, the key being pressed down generates a corresponding key code to the control unit 11. In addition, a human interface device usage table (HID Usage Table) is defaulted in the control unit 11, wherein the HID Usage Table records each one of the keys with a corresponding key code. As a result, it is able to recognize which one of the keys is pressed down. The HID Usage Table is shown as the table below:

| | Key |
|---|---|
| Key | code |
| a A | 04 |
| b B | 05 |
| c C | 06 |
| d D | 07 |
| e E | 08 |
| f F | 09 |
| g G | 0A |
| h H | 0B |
| i I | 0C |
| j J | 0D |
| k K | 0E |
| l L | 0F |
| m M | 10 |
| n N | 11 |
| o O | 12 |
| p P | 13 |
| q Q | 14 |
| r R | 15 |
| s S | 16 |
| t T | 17 |
| u U | 18 |
| v V | 19 |
| w W | 1A |
| x X | 1B |
| y Y | 1C |
| z Z | 1D |
| 1 ! | 1E |
| 2 @ | 1F |
| 3 # | 20 |
| 4 $ | 21 |
| 5 % | 22 |
| 6 \hat{ } | 23 |
| 7 & | 24 |
| 8 * | 25 |
| 9 ( | 26 |
| 0 ) | 27 |
| Return | 28 |
| Escape | 29 |
| Backspace | 2A |
| Tab | 2B |
| Space | 2C |
| - _{—} | 2D |
| = + | 2E |
| [ { | 2F |
| ] } | 30 |
| \ \| | 31 |
| Europe 1 | 32 |
| ; : | 33 |
| ′ ″ | 34 |
| \grave{ } ~ | 35 |
| , < | 36 |
| . > | 37 |
| / ? | 38 |
| Caps Lock | 39 |
| F1 | 3A |
| F2 | 3B |
| F3 | 3C |
| F4 | 3D |
| F5 | 3E |
| F6 | 3F |
| F7 | 40 |
| F8 | 41 |
| F9 | 42 |
| F10 | 43 |
| F11 | 44 |
| F12 | 45 |
| Print Screen | 46 |
| Scroll Lock | 47 |
| Break | 48 |
| (Ctrl-Pause) | |
| Pause | 48 |
| Insert | 49 |
| Home | 4A |
| Page Up | 4B |
| Delete | 4C |
| End | 4D |
| Page Down | 4E |
| Right Arrow | 4F |
| Left Arrow | 50 |
| Down Arrow | 51 |
| Up Arrow | 52 |
| Num Lock | 53 |
| Keypad / | 54 |
| Keypad * | 55 |
| Keypad − | 56 |
| Keypad + | 57 |
| Keypad Enter | 58 |
| Keypad 1 End | 59 |
| Keypad 2 | 5A |
| Down | |
| Keypad 3 | 5B |
| PageDn | |
| Keypad 4 | 5C |
| Left | |
| Keypad 5 | 5D |
| Keypad 6 | 5E |
| Right | |
| Keypad 7 | 5F |
| Home | |
| Keypad 8 | 60 |
| Up | |
| Keypad 9 | 61 |
| PageUp | |
| Keypad 0 | 62 |
| Insert | |
| Keypad . | 63 |
| Delete | |
| Europe 2 | 64 |
| (Note 2) | |
| App | 65 |
| Keyboard | 66 |
| Power | |
| Keypad = | 67 |
| F13 | 68 |
| F14 | 69 |
| F15 | 6A |
| F16 | 6B |
| F17 | 6C |
| F18 | 6D |
| F19 | 6E |
| F20 | 6F |
| F21 | 70 |
| F22 | 71 |
| F23 | 72 |
| F24 | 73 |
| Execute | 74 |
| Help | 75 |
| Menu | 76 |
| Select | 77 |
| Stop | 78 |
| Again | 79 |
| Undo | 7A |
| Cut | 7B |
| Copy | 7C |
| Paste | 7D |
| Find | 7E |
| Mute | 7F |
| Volume Up | 80 |
| Volume Dn | 81 |
| Locking | 82 |
| Caps Lock | |
| Locking | 83 |
| Num Lock | |
| Locking | 84 |
| Scroll Lock | |
| (Brazilian | 85 |
| Keypad .) | |
| Equal Sign | 86 |
| Int'l 1 | 87 |
| Intl'2 | 88 |
| Int'l 3 | 89 |
| Int'l 4 | 8A |
| Int'l 5 | 8B |
| Int'l 6 | 8C |
| Int'l 7 | 8D |
| Int'l 8 | 8E |
| Int'l 9 | 8F |
| Lang 1 | 90 |
| Lang 2 | 91 |
| Lang 3 | 92 |
| Lang 4 | 93 |
| Lang 5 | 94 |
| Lang 6 | 95 |
| Lang 7 | 96 |
| Lang 8 | 97 |
| Lang 9 | 98 |
| Alternate | 99 |
| Erase | |
| SysReq/ | 9A |
| Attention | |
| Cancel | 9B |
| Clear | 9C |
| Prior | 9D |
| Return | 9E |
| Separator | 9F |
| Out | A0 |
| Oper | A1 |
| Clear/Again | A2 |
| CrSel/Props | A3 |
| ExSel | A4 |
| Left Control | E0 |
| Left Shift | E1 |
| Left Alt | E2 |
| Left GUI | E3 |
| Right | E4 |
| Control | |
| Right Shift | E5 |
| Right Alt | E6 |
| Right GUI | E7 |

For example, when the key “C” of the common keys 101 is pressed down by the user, that common key 101 generates the key code “06”, and then the key code “06” is transmitted the control unit 11 via an internal circuit, so that the control unit 11 generates the key signal corresponding to the key code “06” and then transmits the key signal to the electronic apparatus according to the key code “06”. Certainly, the Windows operating system in the electronic apparatus is defaulted with a function command corresponding to that key signal. As a result, the Windows operating system obtains that the command that the user desires to execute is to key in the English letter “C” according to the key signal, and then the electronic apparatus executes that command accordingly. The other results operated by pressing down the other keys are all similar to the above mentioned operation of the common key 101 and thus are omitted herein.

In contrast, when the conventional keyboard device 1 is in communication with an another electronic apparatus (not shown) and the another electronic apparatus is installed with a Macintosh operating system, the operation case is not completely the same. It is because the key signals generated by the conventional keyboard device 1 are always the same, no matter which one of the operating systems is installed in the electronic apparatus. As a result, when the electronic apparatus installed with the Macintosh operating system receives the key signal, the Macintosh operating system may not recognize the command corresponding to the key signal.

Take an example of the key “C” of the above mentioned common keys 101. As the conventional keyboard device 1 generates the key signal corresponding to the key code “06”, the electronic apparatus installed with the Macintosh operating system receives the key signal. Since most of the common keys 10 are capable of being commonly used for both of the Windows operating system and the Macintosh operating system, the Macintosh operating system can enable the electronic apparatus to execute the command of keying in the English letter “C” according to the key signal. Generally speaking, most of the key signals generated by the common keys 10 can be recognized by the Macintosh operating system as described above. However, the Macintosh operating system is not always able to recognize any key combination enabled by at least two keys or any shortcut key having a special function. As a result, a key code generated by either the key combination or the shortcut key must be matched up with the operating system, so as to enable the electronic apparatus to recognize any one of the key codes generated by one of the key combinations or the shortcut keys, and then a key combination command corresponding to one of the key codes or a shortcut key command corresponding to one of the shortcut key is capable of being executed.

Take an example of a Copy command of the key combination commands. The Copy command in the Windows operating system is able to be executed by pressing down the key “Ctrl” and the key “C” of the common keys 101 of the conventional keyboard device 1 together. When the user presses down the key “Ctrl” and the key “C” of the common keys 101 of the conventional keyboard device 1 together, a key code “E0” corresponding to the key “Ctrl” and a key code “06” corresponding to the key “C” are generated and then transmitted to the control unit 11. As a result, the control unit 11 outputs a key signal corresponding to the above mentioned key codes to the electronic apparatus according to the above mentioned key codes. Next, the electronic apparatus installed with the Windows operating system can recognize that the key signal corresponds to the Copy command and execute the Copy command. However, the Copy command in the Windows operating system is unable to be used in the Macintosh operating system.

Referring to FIG. 2, which illustrates an external structural schematic view of a conventional keyboard device applied to a Macintosh operating system. Comparing FIG. 1 with FIG. 2, it can be understood that a plurality of keys 20 of the conventional keyboard device 2 applied to the Macintosh operating system are not all the same as the plurality of keys 10 of the conventional keyboard device 1. For example, the plurality of keys 20 comprises an Apple key 201 (also called Command key) and a Clear key 202, but does not have the Num Lock key. When the conventional keyboard device 2 in communication with the electronic apparatus installed with the Windows operating system, the Windows operating system is unable to recognize key signals generated by the Apple key 201 and the Clear key 202, and thus corresponding commands are unable to be executed.

A Copy command in the Macintosh operating system is executed by pressing down the Apple key 201 and the key “C” together, so as to enable the conventional keyboard device 2 to generate a key signal corresponding to the Apple key 201 and the key “C”. When the electronic apparatus installed with the Macintosh operating system receives the key signal, the Macintosh operating system recognizes the key signal as a Copy command, so as to enable the electronic apparatus to execute the Copy command. In another word, when the user presses down the key “Ctrl” and the key “C” of the common keys 101 in the conventional keyboard device 1 together, the electronic apparatus installed with the Macintosh operating system would not execute the Copy command. Similarly, when the user presses down the Apple key 201 and the key “C” in the conventional keyboard device 2 together, the electronic apparatus installed with the Windows operating system would not execute the Copy command as well.

An operation instance of the shortcut key is illustrated hereinafter. As illustrated in FIG. 1, the conventional keyboard device 1 further comprises a first shortcut function key 105 and a second shortcut function key 106, while the key signal generated by the first shortcut function key 105 defaulted in the Windows operating system 21 corresponds to a command for playing the multi media player, and the key signal generated by the second shortcut function key 106 defaulted in the Windows operating system 21 corresponds to a command for stopping playing the multi media player. As a result, when the user presses down the first shortcut function key 105 and thus enables the electronic apparatus installed with the Windows operating system to recognize the key signal thereof, the command for playing the multi media player is executed. In contrast, when the user presses down the second shortcut function key 106 and thus enables the electronic apparatus installed with the Windows operating system to recognize the key signal thereof, the command for stopping playing the multi media player is executed.

However, the commands corresponding to the first shortcut function key 105 and the second shortcut function key 106 defaulted in the Macintosh operating system may be different from those defaulted in the Windows operating system. For example, the key signal generated by the first shortcut function key 105 defaulted in the Macintosh operating system may correspond to a command for stopping playing the multi media player, while the key signal generated by the second shortcut function key 106 defaulted in the Macintosh operating system may correspond to a command for playing the multi media player. As a result, when the user presses down the first shortcut function key 105 and thus enables the electronic apparatus installed with the Macintosh operating system to recognize the key signal thereof, the command for stopping playing the multi media player is executed. In contrast, when the user presses down the second shortcut function key 106 and thus enables the electronic apparatus installed with the Macintosh operating system to recognize the key signal thereof, the command for playing the multi media player is executed. In another word, the commands defaulted in the Macintosh operating system may be just contrary to those defaulted in the Windows operating system.

In summary, a keyboard device capable of being applied to two different operating systems is not yet commercially available. As a result, the user needs to remember two different methods for inputting the same key command for the Windows operating system and the Macintosh operating system. For example, the method for inputting the copy command in the Windows operating system is pressing down the key “Ctrl” and the key “C” together, while that in the Macintosh operating system is pressing down the Apple key and the key “C” together, and thus an input error may be occurred due to the user is likely to be confused in operation.

### SUMMARY OF THE INVENTION

The present invention is directed to providing a keyboard device capable of being applied to different operating systems.

The present invention is further directed to providing a keyboard device capable of being applied to different operating systems and conforming to the user's operation habit.

In a preferred embodiment, the present invention provides a keyboard device for different operating systems, which is in communication with an electronic apparatus, and the keyboard device comprises:
at least one key, exposed by a surface of the keyboard device, wherein the at least one key is capable of being pressed down and thus correspondingly generates a first key code, so as to enable the electronic apparatus installed with a first operating system to execute a first key command, or enable the electronic apparatus installed with a second operating system to execute a second key command; and
a control unit, in communication with the at least one key and the electronic apparatus and capable of receiving the first key code, wherein the control unit comprises:
   a memory unit, storing the first key code and a second key code, wherein the second key code is capable of enabling the electronic apparatus installed with the second operating system to execute the first key command; and
   a logic unit, in communication with the memory unit, the at least one key and the electronic apparatus, capable of recognizing which one of the first operating system and the second operating system is installed in the electronic system and determining a key signal to be outputted according to a recognition result, wherein the logic unit receives the first key code and then outputs a first key signal corresponding to the first key code when the electronic apparatus is installed with the first operating system, so as to enable the electronic apparatus installed with the first operating system to execute the first key command in response to the first key signal, while the logic unit receives the first key code, switches the first key code into the second key code and then outputs a second key signal corresponding to the second key code when the electronic apparatus is installed with the second operating system, so as to enable the electronic apparatus installed with the second operating system to execute the first key command in response to the second key signal.

In a preferred embodiment, the control unit further comprises an auto install program. Herein, the auto install program is activated when the keyboard device is in communication with the electronic apparatus, so as to automatically install a recognition program into the electronic apparatus. In addition, the electronic apparatus transmits a recognition signal to the control unit after the recognition program is installed, so as to enable the logic unit to determine which one of the first operating system and the second operating system is installed in the electronic apparatus according to the recognition signal.

In a preferred embodiment, the present invention further comprises a connection wire, which is capable of being in communication with the electronic apparatus for either transmitting the first key signal to the electronic apparatus or transmitting the recognition signal to the control unit, wherein the keyboard device is a wired keyboard device.

In a preferred embodiment, the electronic apparatus further comprises a recognition program, wherein the recognition program controls the electronic apparatus to transmit a recognition signal to the control unit when the keyboard device is in communication with the electronic apparatus, so as to enable the logic unit to determine which one of the first operating system and the second operating system is installed in the electronic apparatus according to the recognition signal.

In a preferred embodiment, the keyboard device for different operating systems of the present invention further comprises:
a wireless signal emitter, disposed within the keyboard device, in communication with the control unit, and capable of transmitting the first key signal, the second key signal and the recognition signal; and
a wireless signal receiver, which is capable of being plugged in the electronic apparatus for receiving the first key signal and either transmitting the first key signal to the electronic apparatus or transmitting the recognition signal to the wireless signal emitter, wherein the keyboard device is a wireless keyboard device.

In a preferred embodiment, a key cap surface of the at least one key is presented with a play character for a multi media player, and the first key command is a function for playing the multi media player.

In a preferred embodiment, the keyboard device for different operating systems of the present invention further comprises an another key, wherein the another key is exposed by the surface of the keyboard device, capable of being pressed down and thus correspondingly generates an another first key code, so as to enable the electronic apparatus installed with the first operating system to execute the second key command. In addition, a key cap surface of the another key is presented with a stop playing character for a multi media player, and the second key command is a function for stopping playing the multi media player.

In a preferred embodiment, the electronic apparatus is a desktop host, a notebook or a smart phone, the first operating system and the second operating system are any two of a Windows operating system, a Macintosh operating system, an Android operating system and an iOS operating system, and the second operating system is different from the first operating system.

In a preferred embodiment, the first key signal or the second key signal is generated by the control unit in response to the at least one key being pressed down alone, and the at least one key is a shortcut function key.

In a preferred embodiment, the first key signal or the second key signal is generated by the control unit in response to a key combination comprising the at least one key being pressed down together, and the at least one key is a common key.

In a preferred embodiment, the memory unit stores a HID usage table, and the first key code is any one of key codes originally comprised in the HID usage table including a key code “04” to a key code “E7” and a key code “F0”, while the second key code is a key code “F2” additionally added into the HID usage table.

### BRIEF DESCRIPTION OF THE DRAWINGS

FIG. 1 illustrates an external structural schematic view of a conventional keyboard device.

FIG. 2 illustrates an external structural schematic view of a conventional keyboard device applied to a Macintosh operating system.

FIG. 3 illustrates an external structural schematic view of a keyboard device capable of being applied to different operating systems according to a first preferred embodiment of the present invention.

FIG. 4 illustrates an operation block diagram of a keyboard device capable of being applied to different operating systems and in communication with an electronic apparatus installed with a first operating system according to a first preferred embodiment of the present invention.

FIG. 5 illustrates an operation block diagram of a keyboard device capable of being applied to different operating systems and in communication with an electronic apparatus installed with a second operating system according to a first preferred embodiment of the present invention.

FIG. 6 illustrates an external structural schematic view of a keyboard device capable of being applied to different operating systems and in communication with an electronic apparatus according to a second preferred embodiment of the present invention.

FIG. 7 illustrates an external structural schematic view of a keyboard device capable of being applied to different operating systems and in communication with an electronic apparatus according to a third preferred embodiment of the present invention.

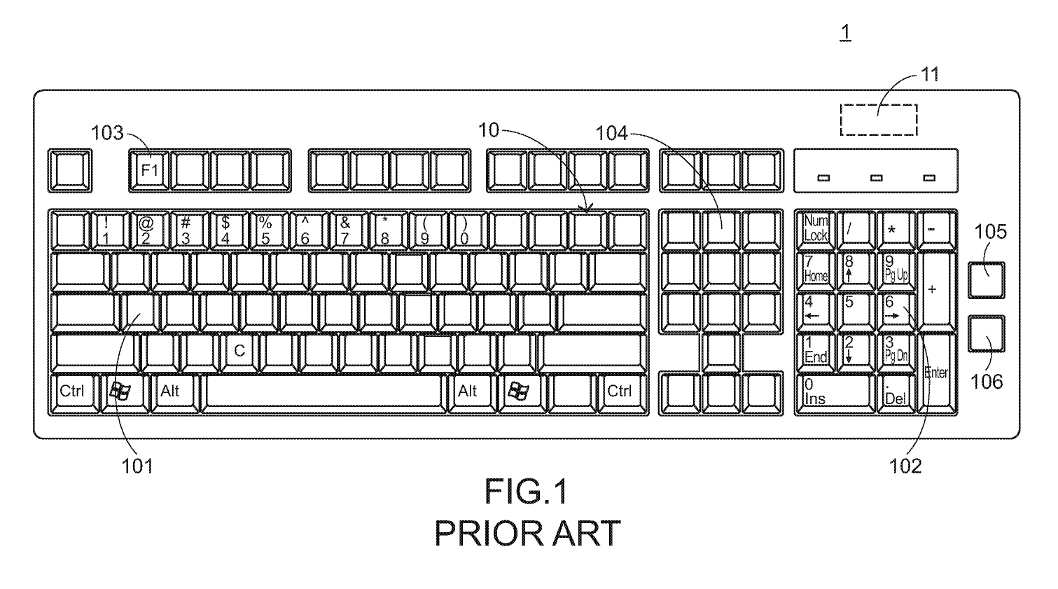

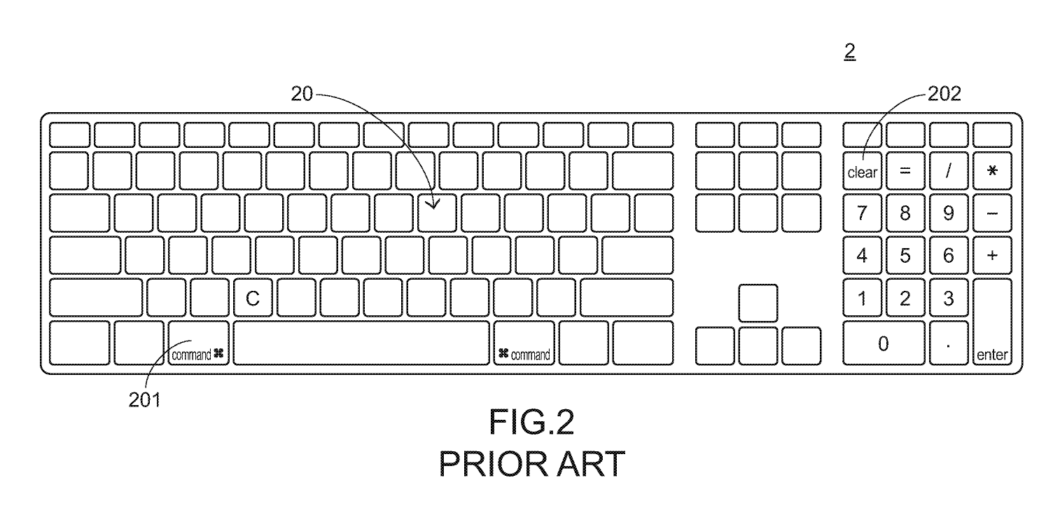

### DETAILED DESCRIPTION OF THE PREFERRED EMBODIMENT

Reference will now be made in detail to specific embodiments of the present invention. Examples of these embodiments are illustrated in the accompanying drawings. While the invention will be described in conjunction with these specific embodiments, it will be understood that it is not intended to limit the invention to these embodiments. In fact, it is intended to cover alternatives, modifications, and equivalents as may be included within the spirit and scope of the invention as defined by the appended claims. In the following description, numerous specific details are set forth in order to provide a through understanding of the present invention. The present invention may be practiced without some or all of these specific details. In other instances, well-known process operations are not described in detail in order not to obscure the present invention.

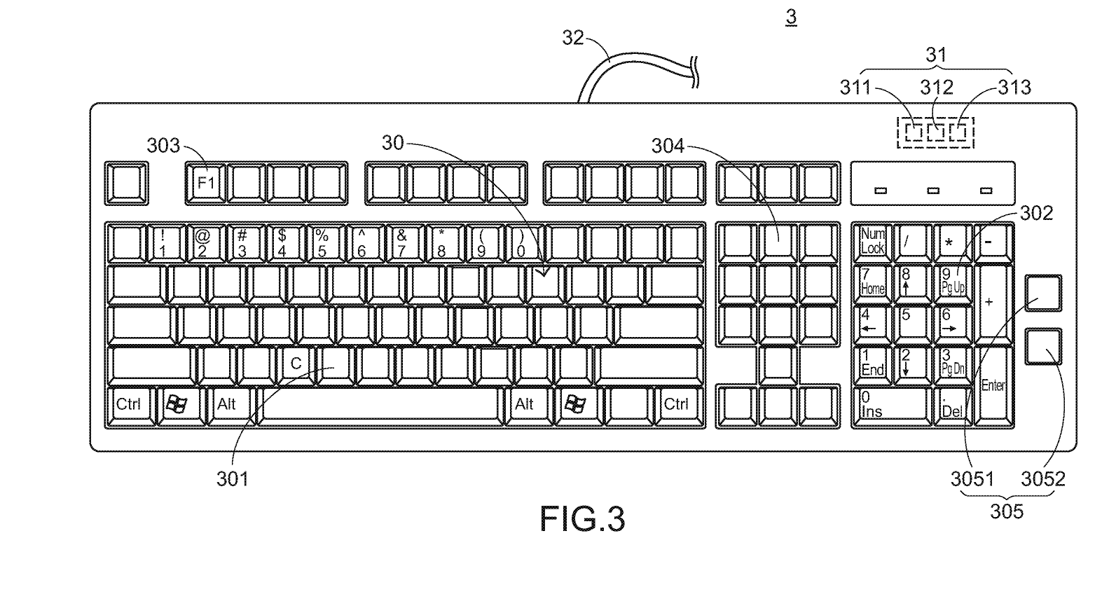

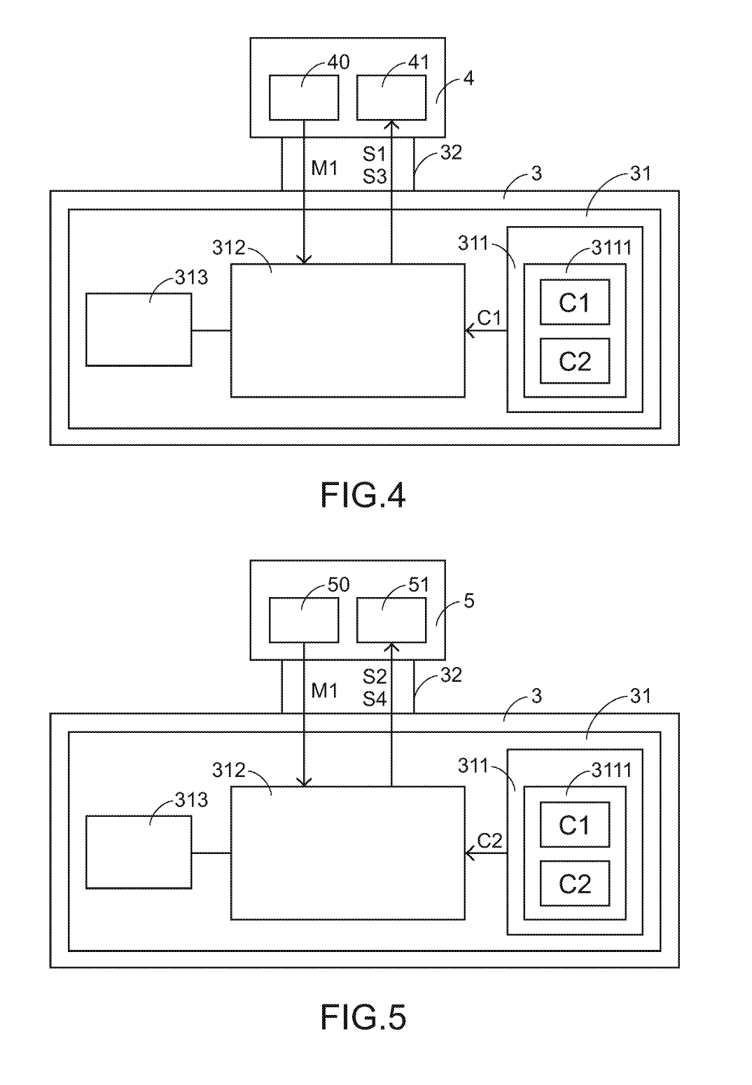

In view of the defects of the conventional arts, the present invention provides a keyboard device capable of making up the disadvantages of the conventional keyboard device. FIG. 3 illustrates an external structural schematic view of a keyboard device capable of being applied to different operating systems according to a first preferred embodiment of the present invention, while FIG. 4 illustrates an operation block diagram of a keyboard device capable of being applied to different operating systems and in communication with an electronic apparatus installed with a first operating system according to a first preferred embodiment of the present invention. Referring to FIG. 3 and FIG. 4 together, the keyboard device 3 capable of being applied to different operating systems is in communication with an electronic apparatus 4, and the electronic apparatus 4 is installed with a first operating system 41. In the present preferred embodiment, the electronic apparatus 4 is a desktop host, while the first operating system 41 is a Windows operating system. The keyboard device 3 capable of being applied to different operating systems comprises a plurality of keys 30, a control unit 31 and a connection wire 32. The plurality of keys 30 are exposed by a surface of the keyboard device 3 and divided into common keys 301, number keys 302, function keys 303, expansion keys 304 and shortcut function keys 305. Each one of the above mention keys 30 is capable of being pressed down by a user and thus correspondingly generates a first key code C1. In the present preferred embodiment, the shortcut function keys 305 comprise a first shortcut function key 3051 and a second shortcut function key 3052, and a key cap surface of the first shortcut function key 3051 is presented with a play character for a multi media player, while a key cap surface of the second shortcut function key 3052 is presented with a stop playing character for the multi media player.

The control unit 31 is in communication with the plurality of keys 30 and the electronic apparatus 4, which is capable of receiving the above mentioned first key codes C1, and the control unit 31 comprises a memory unit 311, a logic unit 312 and an auto install program 313. The memory unit 311 stores a HID Usage Table 3111, and the key codes included in the HID Usage Table 3111 further comprises a key code “F0”, a key code “F1”, a key code “F2” and a key code “F3” except the key code “04” to the key code “E7”. The key code “F0” and the key code “F3” correspond to the first shortcut function key 3051, and the key code “F1” and the key code “F2” correspond to the second shortcut function key 3052, wherein the details of the key code “F0”, the key code “F1”, the key code “F2” and the key code “F3” will be further described later. Any one of the key code “04” to the key code “E7”, the key code “F0” and the key code “F1” included in the HID

Usage Table 3111 is defined as one of the above mentioned first key codes C1, while any one the key code “F2” and the key code “F3” is defined as a second key code C2.

In addition, the logic unit 31 is in communication with the memory unit 311, the plurality of keys 30 and the electronic apparatus 4, which is capable of recognizing the operating system installed in the electronic apparatus 4, so as to determine the key signal to be outputted according to the recognition result. Furthermore, the auto install program 313 is capable of being activated when the keyboard device 3 is in communication with the electronic apparatus 4, so as to install a recognition program 40 in the electronic apparatus 4 automatically. After that, the electronic apparatus 4 transmits a first recognition signal M1 to the control unit 31 when the installation of the recognition program 40 is finished, so as to enable the logic unit 31 to recognize the operating system installed in the electronic apparatus 4 based on the first recognition signal M1. In the present preferred embodiment, the memory unit 311 can be practiced by using an Electrically-Erasable Programmable Read-Only Memory (EEPROM) or a Flash Read-Only Memory (Flash ROM), while the logic unit is a microprocessor.

As illustrated in FIG. 4, the keyboard device 3 capable of being applied to different operating systems is in communication with the electronic apparatus 4 by the connection wire 32, wherein the connection wire 32 is a cable with an Universal Serial Bus (USB) interface. The connection wire 32 is capable of transmitting the key signal corresponding to the first key code C 1 to the electronic apparatus 4, or transmitting the first recognition signal M1 to the control unit 31. In another word, the keyboard device 3 is a wired keyboard device.

The operation case of the keyboard device 3 is illustrated hereinafter. Referring to FIG. 4 also, when the keyboard device 3 is in communication with the electronic apparatus 4 via the connection wire 32, the auto install program 313 of the control unit 31 thereof is activated, so that the recognition program 40 is transmitted into the electronic apparatus 4 via the connection wire 32 and automatically installed after the transmission is finished. After the installation of the recognition program 40 is finished, the recognition program 40 transmits the first recognition signal M1 to the control unit 31 via the connection wire 32, so as to enable the logic unit 312 to determine that the electronic apparatus 4 is installed with the first operating system 41. As a result, when any one of the keys 30 is pressed down and thus correspondingly generates a first key code C1, and the first key code C1 is received by the control unit 31, the logic unit 312 can recognize which one of the keys 30 is pressed down according to the first key code C1 and the HID Usage Table 3111. After that, the logic unit 312 outputs the first key signal S1 corresponding to the first key code C1 to the electronic apparatus 4 according to the recognition result provided by the first recognition signal M1, so as to enable the first operating system 41 to recognize the first key signal S1 and then execute the first key command corresponding to the first key signal S1.

FIG. 5 illustrates an operation block diagram of a keyboard device capable of being applied to different operating systems and in communication with an electronic apparatus installed with a second operating system according to a first preferred embodiment of the present invention. Referring to FIG. 5, the keyboard device 3 is in communication with an another electronic apparatus 5 via the connection wire 32, and the another electronic apparatus 5 is installed with a second operating system 51. In the present preferred embodiment, the another electronic apparatus 5 is a desktop host as well, and the second operating system 51 is a Macintosh operating system. After that, the auto install program 313 of the control unit 31 is activated, so that a recognition program 50 is transmitted into the another electronic apparatus 5 via the connection wire 32 and automatically installed after the transmission is finished. After the installation of the recognition program 50 is finished, the recognition program 50 transmits the second recognition signal M2 to the control unit 31 via the connection wire 32, so as to enable the logic unit 312 to determine that the electronic apparatus 5 is installed with the second operating system 51. As a result, when any one of the keys 30 is pressed down and thus correspondingly generates a first key code C1, and the first key code C1 is received by the control unit 31, the logic unit 312 switches the first key code C1 into the second key code C2 according to the recognition result provided by the second recognition signal M2, and then outputs a second key signal S2 corresponding to the second key code C2 to the another electronic apparatus 5, so as to enable the second operating system 51 to recognize the second key signal S2 and then execute a second key command corresponding to the second key signal S2.

Hereinafter take an example by using the first shortcut function key 3051 and the second shortcut function key 3052. As illustrated in FIG. 4, when the keyboard device 3 is in communication with the electronic apparatus 4, the logic unit 312 thereof obtains that the operating system installed in the electronic apparatus 4 is the first operating system 41 according to the first recognition signal M1. In addition, when the first shortcut function key 3051 is pressed down by the user, the first shortcut function key 3051 generates the first key code C1 (i.e. the key code “F0” corresponding to the first shortcut function key 3051) to the control unit 31. Since the electronic apparatus 4 is installed with the first operating system 41, the logic unit 312 outputs the first key signal 51 corresponding to the first key code C1 (i.e. the key code “F0”) to the electronic apparatus 4, so as to enable the first operating system 41 to execute the first key command (i.e. the command for playing the multi media player) according to the first key signal S1. In contrast, when the second shortcut function key 3052 is pressed down by the user, the second shortcut function key 3052 generates an another first key code C1 (i.e. the key code “F1” corresponding to the second shortcut function key 3052) to the control unit 31. Since the electronic apparatus 4 is installed with the first operating system 41, the logic unit 312 outputs a third key signal S3 corresponding to the another first key code C1 (i.e. the key code “F1”) to the electronic apparatus 4, so as to enable the first operating system 41 to execute the second key command (i.e. the command for stopping playing the multi media player) according to the third key signal S3.

As illustrated in FIG. 5, when the keyboard device 3 is in communication with the another electronic apparatus 5, the logic unit 312 thereof obtains that the operating system installed in the another electronic apparatus 5 is the second operating system 51 according to the second recognition signal M2. In addition, when the first shortcut function key 3051 is pressed down by the user, the first shortcut function key 3051 generates the first key code C1 (i.e. the key code “F0” corresponding to the first shortcut function key 3051) to the control unit 31. Since the another electronic apparatus 5 is installed with the second operating system 51, the logic unit 312 switches the first key code C1 (i.e. the key code “F0”) to the second key code C2 (i.e. the key code “F2” corresponding to the first shortcut function key 3051) by the HID Usage Table 3111 in the memory unit 311. After that, the logic unit 312 outputs the second key signal S2 corresponding to the second key code C2 (i.e. the key code “F2”) to the another electronic apparatus 5, so as to enable the second operating system 51 to execute the first key command (i.e. the command for playing the multi media player) according to the second key signal S2.

In contrast, when the second shortcut function key 3052 is pressed down by the user, the second shortcut function key 3052 generates an another first key code C1 (i.e. the key code “F1” corresponding to the second shortcut function key 3052) to the control unit 31. Since the another electronic apparatus 5 is installed with the second operating system 51, the logic unit 312 switches the another first key code C1 (i.e. the key code “F1”) to an another second key code C2 (i.e. the key code “F3” corresponding to the second shortcut function key 3052) by the HID Usage Table 3111 in the memory unit 311. After that, the logic unit 312 outputs a fourth key signal S4 corresponding to the another second key code C2 (i.e. the key code “F3”) to the another electronic apparatus 5, so as to enable the second operating system 51 to execute the second key command (i.e. the command for stopping playing the multi media player) according to the fourth key signal S4.

In a word, the function of the first shortcut function key 3051 in the first operating system 41 is a function for playing multi media player, but the function of the second shortcut function key 3052 in the first operating system 41 is a function for stopping playing the multi media player. In contrast, the function of the first shortcut function key 3051 in the second operating system 51 is the function for stopping playing multi media player, but the function of the second shortcut function key 3052 in the second operating system 51 is the function for playing the multi media player. However, the keyboard device 3 of the present invention is capable of recognizing the operating system installed in the electronic apparatus by itself and determining that it is necessary to switch the key code or not according to the recognition of the operating system. As a result, the function of the first shortcut function key 3051 is identical to the character presented on the key cap of the first shortcut function key 3051, and thus the user does not need to remember what the function of the first shortcut function key 3051 in whether the first operating system 41 or the second operating system 51 is.

With regard to the key combinations, the functions thereof are similar as well, and hereinafter take a simple example by using the copy function. As illustrated in FIG. 4, when the keyboard device 3 is in communication with the electronic apparatus 4, the logic unit 312 thereof obtains that the operating system installed in the electronic apparatus 4 is the first operating system 41 according to the first recognition signal M1. In addition, when the key “Ctrl” and the key “C” of the keys 30 are pressed down by the user together, the key “Ctrl” and the key “C” generate the first key codes C1 (i.e. the key code “E0” corresponding to the key “Ctrl” and the key code “06” corresponding to the key “C”) to the control unit 31. Since the electronic apparatus 4 is installed with the first operating system 41, the logic unit 312 outputs the first key signal 51 corresponding to the first key codes C1 (i.e. the key code “E0” and the key code “06”) to the electronic apparatus 4, so as to enable the first operating system 41 to execute the first key command (i.e. the command for copying in the first operating system 41) according to the first key signal 51.

As illustrated in FIG. 5, when the keyboard device 3 is in communication with the another electronic apparatus 5, the logic unit 312 thereof obtains that the operating system installed in the another electronic apparatus 5 is the second operating system 51 according to the second recognition signal M2. In addition, when the key “Ctrl” and the key “C” of the keys 30 are pressed down by the user together, the key “Ctrl” and the key “C” of the keys 30 generate the first key codes C1 (i.e. the key code “E0” corresponding to the key “Ctrl” and the key code “06” corresponding to the key “C”) to the control unit 31. Since the another electronic apparatus 5 is installed with the second operating system 51, the logic unit 312 switches the first key codes C1 (i.e. the key code “E0” and the key code “06”) to the second key codes C2, wherein the second key codes C2 comprise the key code corresponding to the Apple key (for example the key code “F4”) and the key code “06”. After that, the logic unit 312 outputs the second key signal S2 corresponding to the second key codes C2 (i.e. the key code “F4” and the key code “06”) to the another electronic apparatus 5, so as to enable the second operating system 51 to execute the first key command (i.e. the command for copying in the second operating system 51) according to the second key signal S2.

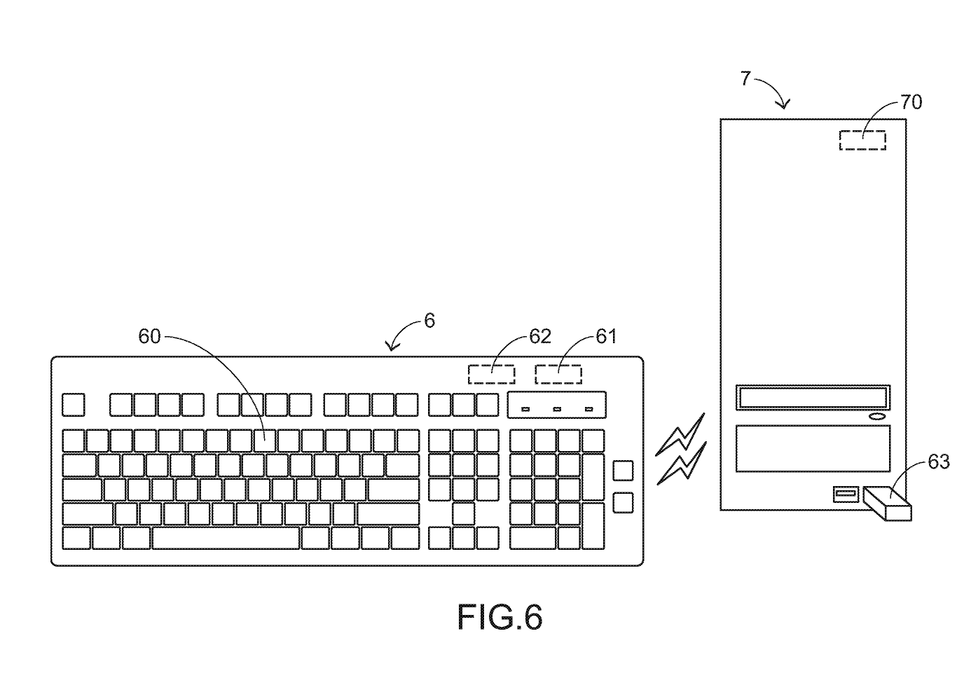

In addition, the present invention further provides a second preferred embodiment to the keyboard device capable of being applied to different operating systems. FIG. 6 illustrates an external structural schematic view of a keyboard device capable of being applied to different operating systems and in communication with an electronic apparatus according to a second preferred embodiment of the present invention. Referring to FIG. 6, the keyboard device 6 capable of being applied to different operating systems comprises a plurality of keys 60, a control unit 61, a wireless signal emitter 62 and a wireless signal receiver 63. The plurality of keys 60 and the control unit 61 are substantially similar to those in the first preferred embodiment and are omitted herein. The difference between these two preferred embodiments is merely about that the control unit 61 does not have the auto install program. In addition, the wireless signal emitter 62 is disposed within the keyboard device 6, in communication with the control unit 61, and capable of transmitting the first key signal, the second key signal, the first recognition signal and the second recognition signal. Besides, the wireless signal receiver 63 is capable of being plugged in an electronic apparatus 7 and capable of receiving the first key signal and the second key signal by using a wireless transmission technology. Further, the wireless signal receiver 63 is capable of transmitting the first key signal and the second key signal to the electronic apparatus 7, or transmitting the recognition signal and the second key signal to the wireless signal emitter 62 by using a wireless transmission technology. In the present preferred embodiment, the keyboard device 6 is a wireless keyboard device, and the electronic apparatus 7 is a desktop host.

Moreover, the electronic apparatus 7 can further comprise a recognition program 70. When the keyboard device 6 is in communication with the electronic apparatus 7, the recognition program 70 controls the electronic apparatus 7 to transmit the first recognition signal or the second recognition signal to the control unit 61, so as to enable the control unit 61 to recognize that the electronic apparatus 7 is installed with the first operating system according to the first recognition signal or installed with the second operating system according to the second recognition signal. Herein, when the electronic apparatus 7 is installed with the first operating system, the recognition program 70 is able to control the electronic apparatus 7 to transmit the first recognition signal to the control unit 61. In contrast, when the electronic apparatus 7 is installed with the second operating system, the recognition program 70 is able to control the electronic apparatus 7 to transmit the second recognition signal to the control unit 61. In the present preferred embodiment, the recognition program 70 is previously installed in the electronic apparatus 7, wherein the recognition program 70 can be stored in the electronic apparatus 7 by being downloaded with a network, or the recognition program 70 can be stored in the electronic apparatus 7 by using an external storage device (such as a flash device, an external hard disk device, an optical disk and so on). With regard to the keyboard device 6 capable of being applied to different operating systems, an operation case thereof is substantially similar to the first preferred embodiment except the signals are transmitted by using the wireless transmission technology, and thus it is omitted herein.

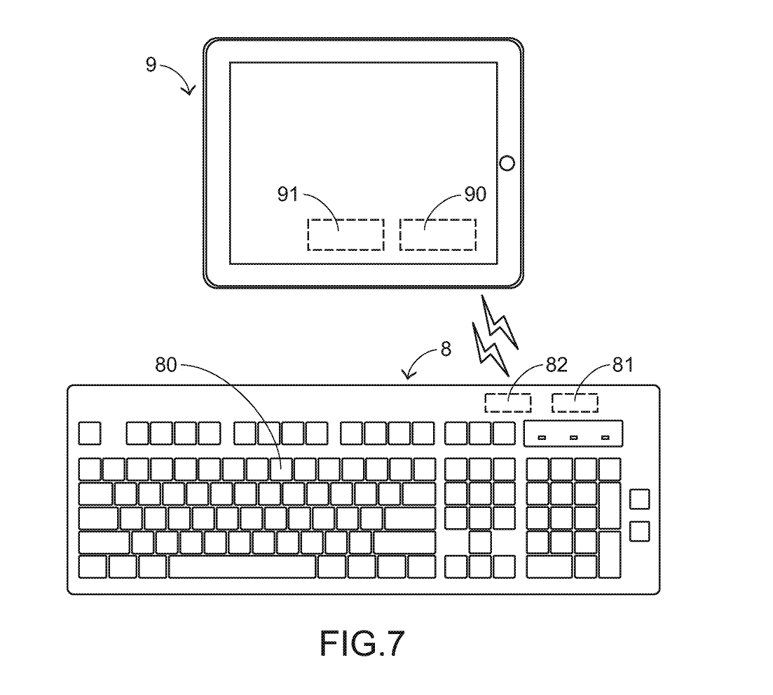

Moreover, the present invention further provides a third preferred embodiment to the keyboard device capable of being applied to different operating systems as well. FIG. 7 illustrates an external structural schematic view of a keyboard device capable of being applied to different operating systems and in communication with an electronic apparatus according to a third preferred embodiment of the present invention. Referring to FIG. 7, the keyboard device 8 capable of being applied to different operating systems comprises a plurality of keys 80, a control unit 81 and a first bluetooth transmission module 82. The plurality of keys 80 and the control unit 81 are substantially similar to the keyboard device 6 in the second preferred embodiment and are omitted herein. The difference between these two preferred embodiments is merely about that the keyboard device 8 is disposed with the first bluetooth transmission module 82. The first bluetooth transmission module 82 is disposed within the keyboard device 8, in communication with the control unit 71, and capable of transmitting the first key signal, the second key signal, the first recognition signal and the second recognition signal.

In addition, an electronic apparatus 9 in communication with the keyboard device 8 comprises a recognition program 90 and a second bluetooth transmission module 91. The recognition program 90 is completely the same as the recognition program 70 disclosed in the second preferred embodiment and thus omitted herein. Further, the second bluetooth transmission module 91 thereof is capable of matching up with the first bluetooth transmission module 82 of the keyboard device 8, so as to establish a connection between the keyboard device 8 and the electronic apparatus 9 for transmitting the first key signal, the second key signal, the first recognition signal and the second recognition signal. In the present preferred embodiment, the electronic apparatus 9 is a tablet personal computer (Tablet PC). With regard to the keyboard device 8 capable of being applied to different operating systems, an operation case thereof is substantially similar to the second preferred embodiment except the signals are transmitted by using the bluetooth transmission technology, and thus it is omitted herein.

In the other preferred embodiments, the electronic apparatus can be practiced by using a smart phone or a notebook personal computer (Notebook PC), while the first operating system and the second operating system can be practiced by using any two of a Windows operating system, a Macintosh operating system, an Android operating system and an iOS operating system, and the second operating system is different from the first operating system.

According to the above mentioned descriptions, it is understood that the keyboard device capable of being applied to different operating systems of the present invention can determine the key signal to be outputted according to the operating system installed within the electronic apparatus. Therefore, the user can press down the desired key in response to the function character presented on the plurality of keys, so as to enable the electronic apparatus to execute the function command corresponding to the function character. As a result, the user does not need to remember the input methods of the function commands for different operating system, and thus the operation of the keyboard device disclosed in the present invention is simpler and more convenient than the conventional keyboard devices.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

According to the above mentioned descriptions, it is understood that the keyboard device of the present invention utilizes a feature of that the first number key and the second number key can key in the same number with different key codes. As a result, a second number key code is correspondingly transferred into a first number key code when the control unit receives a second number key code corresponding to a second number key, so as to key in a number. In addition, a cutoff signal is outputted when the control unit receives the shift key code and the second number key code together, so as to ensure that only a number can be keyed in when any one of the second number keys is pressed down due to the computer host not to execute the commands. As a result, it is unnecessary to switch the functions of the second number keys by using the number lock key when the user operates the keyboard device of the present invention, but the numbers can be keyed in by directly pressing down the second number keys instead, and thus it is convenient to be operated by the user. Certainly, in the keyboard device of the present invention, it is unnecessary to disposed with a number lock indicating lamp corresponding to the number lock key as well.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A keyboard device for different operating systems, which is in communication with an electronic apparatus, wherein the keyboard device comprises:
at least one key, exposed by a surface of the keyboard device, wherein the at least one key is capable of being pressed down and thus correspondingly generates a first key code, so as to enable the electronic apparatus installed with a first operating system to execute a first key command, or enable the electronic apparatus installed with a second operating system to execute a second key command; and
a control unit, in communication with the at least one key and the electronic apparatus and capable of receiving the first key code, wherein the control unit comprises:
a memory unit, storing the first key code and a second key code, wherein the second key code is capable of enabling the electronic apparatus installed with the second operating system to execute the first key command; and
a logic unit, in communication with the memory unit, the at least one key and the electronic apparatus, capable of recognizing which one of the first operating system and the second operating system is installed in the electronic apparatus and determining a key signal to be outputted according to a recognition result, wherein the logic unit receives the first key code and then outputs a first key signal corresponding to the first key code when the electronic apparatus is installed with the first operating system, so as to enable the electronic apparatus installed with the first operating system to execute the first key command in response to the first key signal, while the logic unit receives the first key code, switches the first key code into the second key code and then outputs a second key signal corresponding to the second key code when the electronic apparatus is installed with the second operating system, so as to enable the electronic apparatus installed with the second operating system to execute the first key command in response to the second key signal.

2. The keyboard device for different operating systems as claimed in claim 1, wherein the control unit further comprises an auto install program, the auto install program is activated when the keyboard device is in communication with the electronic apparatus, so as to automatically install a recognition program into the electronic apparatus, and the electronic apparatus transmits a recognition signal to the control unit after the recognition program is installed, so as to enable the logic unit to determine which one of the first operating system and the second operating system is installed in the electronic apparatus according to the recognition signal.

3. The keyboard device for different operating systems as claimed in claim 2, further comprising a connection wire, which is capable of being in communication with the electronic apparatus for either transmitting the first key signal to the electronic apparatus or transmitting the recognition signal to the control unit, wherein the keyboard device is a wired keyboard device.

4. The keyboard device for different operating systems as claimed in claim 1, wherein the electronic apparatus further comprises a recognition program, and the recognition program controls the electronic apparatus to transmit a recognition signal to the control unit when the keyboard device is in communication with the electronic apparatus, so as to enable the logic unit to determine which one of the first operating system and the second operating system is installed in the electronic apparatus according to the recognition signal.

5. The keyboard device for different operating systems as claimed in claim 4, further comprising:
a wireless signal emitter, disposed within the keyboard device, in communication with the control unit, and capable of transmitting the first key signal, the second key signal and the recognition signal; and
a wireless signal receiver, which is capable of being plugged in the electronic apparatus for receiving the first key signal and either transmitting the first key signal to the electronic apparatus or transmitting the recognition signal to the wireless signal emitter, wherein the keyboard device is a wireless keyboard device.

6. The keyboard device for different operating systems as claimed in claim 1, wherein a key cap surface of the at least one key is presented with a play character for a multi media player, and the first key command is a function for playing the multi media player.

7. The keyboard device for different operating systems as claimed in claim 1, further comprising an another key exposed by the surface of the keyboard device, wherein the another key is capable of being pressed down and thus correspondingly generates an another first key code, so as to enable the electronic apparatus installed with the first operating system to execute the second key command, a key cap surface of the another key is presented with a stop playing character for a multi media player, and the second key command is a function for stopping playing the multi media player.

8. The keyboard device for different operating systems as claimed in claim 1, wherein the electronic apparatus is a desktop host, a notebook or a smart phone, the first operating system and the second operating system are any two of a Windows operating system, a Macintosh operating system, an Android operating system and an iOS operating system, and the second operating system is different from the first operating system.

9. The keyboard device for different operating systems as claimed in claim 1, wherein the first key signal or the second key signal is generated by the control unit in response to the at least one key being pressed down alone, and the at least one key is a shortcut function key.

10. The keyboard device for different operating systems as claimed in claim 1, wherein the first key signal or the second key signal is generated by the control unit in response to a key combination comprising the at least one key being pressed down together, and the at least one key is a common key.

11. The keyboard device for different operating systems as claimed in claim 1, wherein the memory unit stores a human interface device usage table, and the first key code is any one of key codes originally comprised in the human interface device usage table including a key code “04” to a key code “E7” and a key code “F0”, while the second key code is a key code “F2” additionally added into the human interface device usage table.
